(19) United States
(12) Patent Application Publication
(10) Pub. No.: US 2024/0258333 A1
(43) Pub. Date: Aug. 1, 2024

(54) DISPLAY APPARATUS

(71) Applicant: LG Display Co., Ltd., Seoul (KR)

(72) Inventors: Seong-Jun CHO, Paju-si (KR); Dae-Hyun NAM, Paju-si (KR); Hyung-Beom SHIN, Paju-si (KR); Se-Eung LEE, Paju-si (KR); Yeon-Gyu CHOI, Paju-si (KR)

(73) Assignee: LG Display Co., Ltd., Seoul (KR)

(21) Appl. No.: 18/541,085

(22) Filed: Dec. 15, 2023

(30) Foreign Application Priority Data
Jan. 31, 2023 (KR) 10-2023-0012456

(51) Int. Cl. H01L 27/12; G02F 1/1362; G02F 1/1368

(52) U.S. Cl. CPC H01L 27/124; G02F 1/136209; G02F 1/136286; G02F 1/1368

(57) ABSTRACT

In one aspect, a display apparatus includes a display panel including a first substrate and a second substrate; a backlight unit facing the first substrate and configured to supply light to the display panel; a color filter layer on the first substrate; a plurality of gate lines and data lines on the second substrate configured to form a plurality of sub-pixels; a thin film transistor in each of the plurality of sub-pixels on the second substrate; a pixel electrode and a common electrode in each of the plurality of sub-pixels; a common line on the second substrate to apply an signal to the common electrode; and a light shielding layer under the common line. The light shielding layer includes a first light shielding layer configured to absorb the light and a second light shielding layer made of a metal.

### CROSS-REFERENCE TO RELATED APPLICATIONS

This application claims priority to and the benefit of Republic of Korea Patent Application No. 10-2023-0012456, filed on Jan. 31, 2023, the contents of which are incorporated herein by reference in its entirety.

### BACKGROUND

### 1. Technical Field

The present disclosure relates to a display apparatus that may minimize the area of a bezel.

### 2. Description of the Related Art

Display apparatuses are important to the increasing consumption of multimedia in today' s world. Various display apparatuses such as a liquid crystal displays apparatus and an organic light emitting display apparatus have been proposed.

As these display apparatuses are applied to small portable electronic apparatuses such as smartphones and tablet PCs, the bezel area must be minimized or eliminated to have a relatively large screen and an attractive appearance even in a small area.

### SUMMARY

An object of the present disclosure is to provide a display apparatus that may minimize the bezel area.

Another object of the present disclosure is to provide the display apparatus that may prevent low image quality due to reflection of external light.

In one aspect, a display apparatus includes a display panel including a first substrate and a second substrate; a backlight unit facing the first substrate and configured to supply light to the display panel; a color filter layer on the first substrate; a plurality of gate lines and data lines on the second substrate configured to form a plurality of sub-pixels; a thin film transistor in each of the plurality of sub-pixels on the second substrate; a pixel electrode and a common electrode in each of the plurality of sub-pixels; a common line on the second substrate to apply an signal to the common electrode; and a light shielding layer under the common line. The light shielding layer includes a first light shielding layer configured to absorb the light and a second light shielding layer made of a metal.

In another aspect, the first light shielding layer is formed of material having an extinction coefficient (K) of 0.6<k<1.2.

In another aspect, the first light shielding layer is formed of a composite material of the metal and a ceramic material.

In another aspect, the metal of the first light shielding layer includes Mo or MoOx, and the ceramic material of the first light shielding layer includes Nb₂O₅.

In another aspect, the display apparatus further includes a connection electrode configured to connect the common line, the light shielding layer, and the common electrode.

In another aspect, the common electrode is on the second substrate and the light shielding layer is on the common electrode.

In another aspect, the thin film transistor includes a gate electrode on the second substrate; a gate insulating layer configured to connect the gate electrode; a semiconductor layer on the gate insulating layer; a source electrode and a drain electrode on the semiconductor layer; and a passivation layer configured to cover the source electrode and the drain electrode.

In another aspect, the gate electrode includes a first gate layer on the second substrate; a second gate layer on the first gate layer; and a third gate layer on the second gate layer.

In another aspect, the first gate layer is formed of the same material as the common electrode, the second gate layer is formed of the same material as the first light shielding layer, and the third gate layer is formed of the same material as the second light shielding layer.

In another aspect, the pixel electrode is on the passivation layer.

In another aspect, a contact hole is formed in the passivation layer and the connection electrode is formed in the contact hole.

In another aspect, the connection electrode is formed of the same material as the pixel electrode.

In another aspect, adjacent sub-pixels of the plurality of sub-pixels share the data line.

In one aspect, a display apparatus includes a first substrate; a backlight unit facing the first substrate; a second substrate configured as a screen on the first substrate to display an image; a printed circuit board attached to the second substrate and configured to control transmission of light onto the second substrate; a color filter layer on the first substrate; a plurality of sub-pixels on the second substrate; a thin film transistor in each of the plurality of sub-pixels on the second substrate; and a gate electrode in the thin film transistor having a plurality of gate layers, wherein each of the plurality of gate layers is formed on a different material.

In another aspect, the plurality of gate layers include a first gate layer, a second gate layer, and a third gate layer.

In another aspect, the second gate layer is formed of a synthesized metal.

In another aspect, the display apparatus includes a transparent conductive layer on the second substrate; and a light shielding layer on the transparent conductive layer.

In another aspect, the light shielding layer includes a first light shielding layer and a second light shielding layer.

In another aspect, the second light shielding layer is formed of the same material as the second gate layer.

In another aspect, the display apparatus further includes a passivation layer configured to cover the thin film transistor.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a display device includes: a display panel including a plurality of touch blocks each having a touch electrode; a dummy region at one side of the display panel; a plurality of touch lines connected to the plurality of touch blocks, respectively, and applying a touch signal to the plurality of touch blocks; a repair line disposed in the dummy region; and a dummy pattern in the dummy region.

It is to be understood that both the foregoing general description and the following detailed description are explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a plain view of a display apparatus according to some aspects of the present disclosure;

FIG. 2 is the view showing external light being reflected by signal line in a display apparatus according to some aspects of the present disclosure;

FIG. 3 is an equivalent circuit diagram of a display apparatus according to according to some aspects of the present disclosure;

FIG. 4 is a plain view of a display apparatus according to according to some aspects of the present disclosure;

FIG. 5 is a cross sectional view of a display apparatus according to according to some aspects of the present disclosure; and

FIGS. 6A to 6E are views illustrating a method of manufacturing a display apparatus according to some aspects of the present disclosure.

### DETAILED DESCRIPTION

Advantages and features of the present disclosure and methods for achieving them will be made clear from embodiments described in detail below with reference to the accompanying drawings. The present disclosure may, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains, and the present disclosure is defined only by the scope of the appended claims.

Shapes, sizes, ratios, angles, numbers, and the like disclosed in the drawings for describing the embodiments of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein. When terms such as “including,” “having,” “comprising,” and the like mentioned in this disclosure are used, other parts may be added unless the term “only” is used herein. When a component is expressed as being singular, being plural is included unless otherwise specified.

In analyzing a component, an error range is interpreted as being included even when there is no explicit description.

In describing a positional relationship, for example, when a positional relationship of two parts is described as being “on,” “above,” “below,” “next to,” or the like, unless “immediately” or “directly” is used, one or more other parts may be located between the two parts.

In describing a temporal relationship, for example, when a temporal predecessor relationship is described as being “after,” “subsequent,” “next to,” “prior to,” or the like, unless “immediately” or “directly” is used, cases that are not continuous may also be included.

Although the terms first, second, and the like are used to describe various components, these components are not substantially limited by these terms. These terms are used only to distinguish one component from another component. Therefore, a first component described below may substantially be a second component within the technical spirit of the present disclosure.

In describing the components of the disclosure, terms such as first, second, A, B, (a), (b), etc. may be used. These terms are only for distinguishing the elements from other elements, and the essence, order, or number of the elements are not limited by the terms. When it is described that a component is “coupled” or “connected” to another component, the component may be directly coupled or connected to the other component, but indirectly without specifically stated. It should be understood that other components may be “interposed” between each component that is connected or may be connected.

As used herein, the term “apparatus” may include a display apparatus such as a liquid crystal module (LCM) including a display panel and a driving unit for driving the display panel, and an organic light emitting display module (OLED module). Further, the term “apparatus” may further include a notebook computer, a television, a computer monitor, a vehicle electric apparatus including an apparatus for a vehicle or other type of vehicle, and a set electronic apparatus or a set apparatus such as a mobile electronic apparatus of a smart phone or an electronic pad, etc., which are a finished product (complete product or final product) including LCM and OLED module.

Accordingly, the apparatus in the disclosure may include the display apparatus itself such as the LCM, the OLED module, etc., and the application product including the LCM, the OLED module, or the like, or the set apparatus, which is the apparatus for end users.

This disclosure may be applied to the various display apparatus. For example, the display apparatus of this disclosure may be applied to various display apparatus such as an organic light emitting display apparatus, a liquid crystal display apparatus, an electrophoretic display apparatus, a quantum dot display apparatus, a micro LED (Light Emitting Device) display apparatus, and a mini LED display apparatus. However, in the following description, the organic light emitting display apparatus will be described as an example for convenience of explanation.

Hereinafter, the present disclosure will be described in detail with reference to the attached drawings.

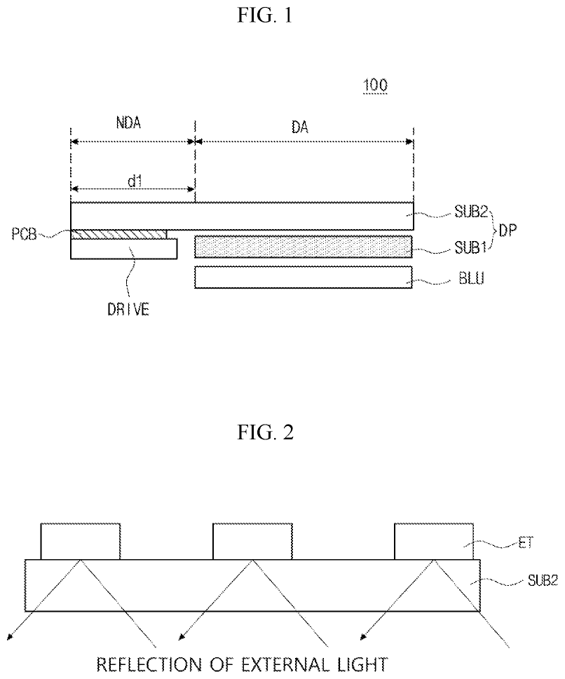

FIG. 1 is a plain view of a display apparatus according to some aspects of the present disclosure.

As shown in FIG. 1, the display apparatus 100 according to the present disclosure includes a color filter substrate SUB1, an array substrate SUB2, and a liquid crystal layer (not shown) between the color filter substrate SUB1 and the array substrate SUB 2. A backlight unit BLU for supplying the light to the liquid crystal panel DP is disposed below the liquid crystal panel DP. An image is displayed by controlling the transmission of the light supplied from the backlight unit BLU by the liquid crystal layer.

Th backlight unit, the array substrate, and the color filter substrate are sequentially arranged from the bottom in the conventional liquid crystal display apparatus, whereas the backlight unit BLU, the color filter substrate SUB1, and the array substrate SUB2 are sequentially arranged from the bottom in the display apparatus 100 according to the present disclosure. That is, compared to the conventional display apparatus, in the display apparatus 100 of the present disclosure, the color filter substrate SUB1 and the array substrate SUB2 are arranged in the opposite order, so that the array substrate SUB2 becomes a screen on which images are displayed.

By this structure, the printed circuit board PCB formed on one side of the array substrate SUB2 is directly attached to the back of the array substrate SUB2, so that the driving signal for controlling the transmission of the light may be applied to the array substrate SUB2. That is, the printed circuit board PCB is disposed directly on the back of the array substrate SUB2 facing the liquid crystal layer, and the driving circuit DRIVE is mounted over the printed circuit board PCB.

As with the conventional liquid crystal display apparatus, one end of the printed circuit board PCB is attached to one portion of the front of the array substrate SUB2, and there is no need to bend the printed circuit board PCB to the back of the array substrate SUB2. Thus, the tack time may be reduced by improving workability. Further, since the non-display area NA consists only of the area d1 where various signal lines and pads are formed, it is possible to manufacture a display apparatus with a narrow bezel area.

FIG. 2 is the view showing external light being reflected by signal line in a display apparatus according to some aspects of the present disclosure. As shown in FIG. 2, the transparent substrate of the array substrate SUB2 is disposed on the front side, so that the external light passing through the transparent substrate is reflected by the various signal lines such as the gate line and data line and the various electrode such as the source electrode and drain electrode of the thin film transistor which are disposed inside the array substrate SUB 2. These reflections cause image quality deterioration.

According to aspects of the present disclosure, the light reflection on the array substrate SUB2 disposed at the front of the display apparatus 100 is minimized, so that the degradation of the quality of the display image may be minimized.

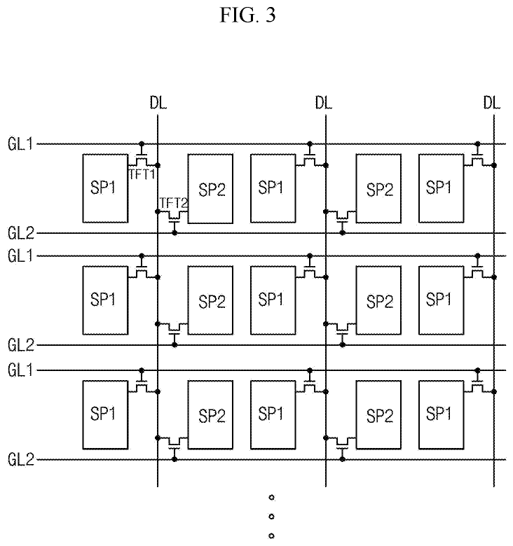

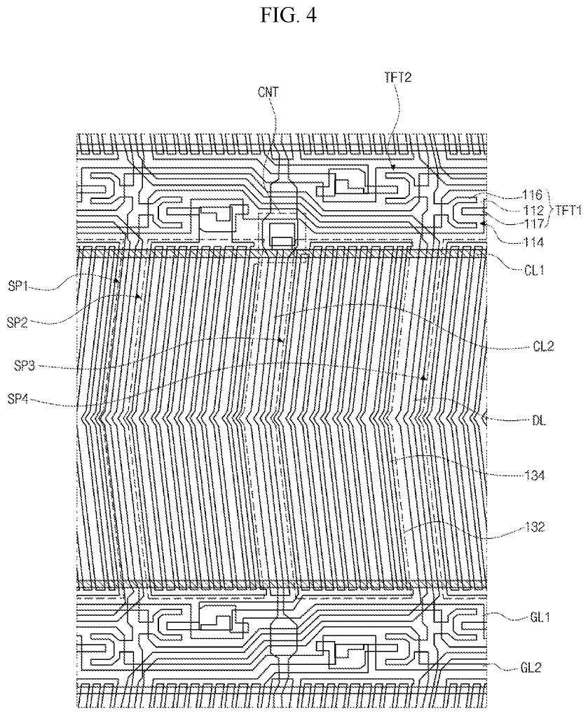

FIG. 3 is an equivalent circuit diagram of the display apparatus 100 according to some aspects of the present disclosure. The display apparatus 100 of the present disclosure is a DRD (Double Rate Driving) display apparatus. In the DRD display apparatus, two adjacent sub-pixels share one data line placed between them, so that the number of expensive data driving element may be reduced by half, thereby reducing manufacturing costs.

As shown in FIG. 3, the display apparatus 100 according to the present disclosure includes first gate lines GL1 and second gate lines GL2 arranged alternately in the horizontal direction, data lines DL arranged alternately in the vertical direction, a first thin film transistor of the first sub-pixel SP1 disposed in the area where the first gate line GL1 and the data line DL intersect, and a second thin film transistor TFT2 of the second sub-pixel SP2 disposed in the area where the second gate line GL2 and the data line DL intersect.

The data line DL is disposed between the first sub-pixel SP1 and the second sub-pixel SP2, and the first thin film transistor TFT1 and the second thin film transistor TFT2 are connected to one data line DL.

Further, the first gate line GL1 disposed between the sub-pixels SP1 andSP2 arranged vertically is connected to the odd-numbered sub-pixels SP1 arranged along the column1, and the second gate line GL2 is connected to the even-numbered sub-pixels SP1.

FIG. 4 is a plain view of a display apparatus according to according to some aspects of the present disclosure. In the display apparatus 100 according to the present disclosure, the gate line 101 and the data line 102 are arranged vertically and horizontally to define a sub-pixel SP. In another examine, in the display apparatus 100, the gate line 101 and the data line 102 are arranged in n×m (where n, m are natural numbers) to define a plurality of sub- pixels SP, but in the figure, for convenience of explanation, only four horizontally adjacent sub-pixels SP1, SP2, SP3, and SP4 are shown.

As shown in FIG. 4, two gate lines GL1 and GL2 are disposed between sub-pixels arranged vertically. Further, a first common line CL1 arranged in parallel with the gate lines GL1 and GL2 is disposed in the sub-pixels SP1, SP2, SP3, and SP4.

The data lines DL are disposed between the horizontally adjacent first and second sub-pixels SP1 and SP2 and between the horizontally adjacent third and fourth sub-pixels SP3 and SP4, and a second common line CL2 is disposed between the second and third sub-pixels SP2 and SP3.

The first common line CL1 is arranged in parallel with the gate lines GL1 and GL2 and the second common line CL2 is arranged in parallel with the data line DL. The first common line CL1 and the second common line CL2 are arranged perpendicular to each other. The first common line CL1 and the second common line CL2 may be formed integrally, but the formation of the first common line CL1 and the second common line CL2 is not limited thereto.

A common electrode 132 and a pixel electrode 134 are disposed in the first to fourth sub-pixels SP1, SP2, SP3, and SP4. The common electrode 132 is formed approximately in the entire area of the subpixels SP1, SP2, SP3, and SP4. That is, the common electrode 132 is formed in the same shape as the sub-pixels SP1, SP2, SP3, and SP4 and is disposed in the entire area of the sub-pixels SP1, SP2, SP3, and SP4. A plurality of pixel electrodes 134 are arranged in parallel with the data line DL in the sub-pixels SP1, SP2, SP3, and SP4, each of the pixel electrodes 134 has a strip shape with a predetermined width.

Two thin film transistors TFT1 and TFT2 are disposed between the first gate line GL1 and the second gate line GL2. Each of the first and second thin film transistors TFT1 and TFT2 includes a gate electrode 112, a semiconductor layer 114, a source electrode 116, and a drain electrode 117.

The gate electrode 112 of the first thin film transistor TFT1 is connected to the first gate line GL1 so that a first scan signal may be applied from the outside to the gate electrode 112 through the first gate line GL1. The gate electrode 112 of the second thin film transistor TFT2 is connected to the second gate line GL2 so that a second scan signal may be applied from the outside to the second gate electrode through the second gate line GL2.

The source electrodes 116 of the first thin film transistor TFT1 and the second thin film transistor TFT2 are connected to the same data line DL, and an image signal is applied from the outside to the source electrode 116 through the data line DL. The drain electrodes 117 of the first thin film transistor TFT1 and the second thin film transistor TFT2 are respectively connected to the pixel electrodes 134 disposed in the corresponding sub-pixels so that the first and second thin film transistors TFT1 and TFT2 are turned on by the first and second scan signals from the outside and thus the image signals are applied to the pixel electrodes 134 of the corresponding sub-pixels through the data line DL.

The common electrode 132 is electrically connected to the first common line CL1 so that an external common voltage is applied to the common electrode 132 through the first and second common lines CL1 and CL2. An electric field is generated between the common electrode 132 and the pixel electrode 134 by the potential difference between the common voltage of the common electrode 132 and the image signal (data voltage) of the pixel electrode 134. The arrangement direction of the liquid crystal molecules in the liquid crystal layer is changed by the electric field to control the transmittance of light passing through the liquid crystal layer, thereby displaying images.

The common electrode 132 and the first common line CL1 are electrically connected through a connection portion CNT, which will be described in detail later.

Since the display apparatus 100 has the array substrate disposed on the screen side, the external light is reflected by various signal lines and electrodes disposed on the array substrate, thereby deteriorating image quality. To minimize the reflection of the external light, aspects of the disclosure describe a low-reflective material being disposed below the signal lines and/or electrode to absorb the light incident on the signal lines and/or electrodes.

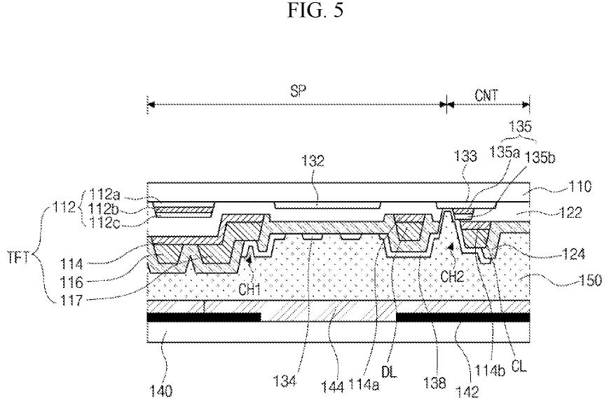

FIG. 5 is a cross sectional view of a display apparatus according to according to some aspects of the present disclosure.

As shown in FIG. 5, the display apparatus 100 includes a display panel DP having the sub-pixel SP and the connection portion CNT and a backlight unit BLU. The backlight unit BLU is disposed below the display panel DP to supply the light to the display panel DP.

The backlight unit BLU may include various light sources. For example, the backlight unit BLU may include a fluorescent lamp such as a cold cathode fluorescent lamp or an external electrode fluorescent lamp, or a light emitting diode LED, but is not limited thereto.

The thin film transistor TFT is disposed in the sub-pixel SP of the second substrate 110. The thin film transistor TFT includes the gate electrode 112 formed on the upper surface of the second substrate 110 (i.e., the surface facing the first substrate 140), a gate insulating layer 122 formed on the gate electrode 112, a semiconductor layer 114 formed on the gate insulating layer 122, and a source electrode 116 and a drain electrode 117 formed on the semiconductor layer 114 and spaced a certain distance away from each other.

The gate electrode 112 includes a first gate layer 112a, a second gate layer 112b, and a third gate layer 112c. The first gate layer 112a may be formed of a transparent metal oxide such as indium tin oxide (ITO) or indium zinc oxide (IZO), but is not limited thereto.

The second gate layer 112b may be formed of a low reflection material with good light absorption. For example, the second gate layer 112b may be formed of a composite material of the metal such as Mo or MoOx and a ceramic material such as Nb₂O₅. Mo and MoOx have good absorption characteristics with an extinction coefficient (K) of about 3-4, but their etching characteristics are not good. Therefore, when forming the second gate layer with Mo or MoOx, the reflection of the external light may be minimized. However, since the etching characteristics of these metals is poor, it is practically impossible to form the second gate layer by patterning these metals. On the other hand, Nb₂O₅ has poor light absorption characteristics but good etching characteristics.

In the first aspect of the present disclosure, the second gate layer 112b may be formed with the material having good low reflection characteristics and good etching characteristics by synthesizing the metal such as Mo or MoOx and the ceramic material such as Nb₂O₅. According to the present disclosure, the second gate layer 112b formed by synthesizing the metal such as Mo or MoOx and the ceramic material such as Nb₂O₅ may have the extinction coefficient of about 0.6<k<1.2.

The third gate metal layer 112c may be formed of copper (Cu), but is not limited to this metal, and any metal with good conductive characteristics such as aluminum (Al), gold (Au), silver (Ag), etc. may be used.

In one example, the layer made of transparent metal oxide may be omitted in the gate electrode 112. That is, the gate electrode 112 may be formed only of the first gate layer made of the composite material of the metal such as Mo or MoOx and the ceramic material such as Nb₂O₅ and the second gate layer made of the metal.

As described above, in the display apparatus 100 according to the present disclosure, since the gate electrode 112 formed on the second substrate 110 which is the image displaying surface includes the second gate layer 112b made of low reflection materials below the third gate layer 112c made of the metal, the reflection of the external light from the gate electrode 112 may be minimized by the second gate layer 112b and thus the image deterioration caused by the reflection of the external light may be prevented.

The semiconductor pattern 114 may be made of an amorphous semiconductor or a polycrystalline semiconductor. For example, the polycrystalline semiconductor may be made of low temperature poly silicon (LTPS) having high mobility, but is not limited thereto.

The semiconductor layer 114 may be made of an oxide semiconductor. For example, semiconductor layer 114 may be made of one of IGZO (Indium-gallium-zinc-oxide), IZO (Indium-zinc-oxide), IGTO (Indium-gallium-tin-oxide), and IGO (Indium-gallium-oxide), but is not limited thereto. The semiconductor layer 114 may include a channel region in a central region and a source region and a drain region which are doped layers at both sides of the channel region.

The source electrode 116 and the drain electrode 117 may be formed of the single layer or multi layers made of one or alloys of molybdenum (Mo), aluminum (Al), chromium (Cr), gold (Au), titanium (Ti), nickel (Ni), neodymium (Nd), and copper (Cu), but the present disclosure is not limited thereto.

The data line DL is disposed on the gate insulating layer 122 in the sub-pixel SP, and a first semiconductor pattern 114a is disposed below the data line DL. At this time, the first semiconductor pattern 114a may be omitted and the data line DL may be directly disposed on the gate insulating layer 122.

A transparent conductive layer 133 is disposed on the second substrate 110 in the connection portion CNT, and a light shielding layer 135 is disposed on the transparent conductive layer 133. Although not shown in the figure, the transparent conductive layer 133 is electrically connected to the common electrode 132. The transparent conductive layer 133 may be formed integrally with the common electrode 132. In this respect, the transparent conductive layer 133 may be a part of the common electrode 132.

The light shielding layer 135 includes a first light shielding layer 135a and a second light shielding layer 135b thereon. The first light shielding layer 135a may be made of the same material as the second gate layer 112b of the gate electrode 112. The second light shielding layer 135b may be made of the same material as the third gate layer 112c of the gate electrode 112. That is, the first light shielding layer 135a may be formed of the composite material of the metal such as Mo or MoOx and the ceramic material such as Nb₂O₅. However, the first light shielding layer 135a is not limited to these materials and may be made of black resin or the like.

A second semiconductor pattern 114b is disposed on the gate insulating layer 122 of the connection portion CNT, and the common line CL is formed on the second semiconductor pattern 114b. The common line CL may be made of the same metal as the source electrode 116 and the drain electrode 117 of the thin film transistor TFT, but is not limited to this material. At this time, the second semiconductor pattern 114b may be omitted and the common wiring CL may be formed directly on the gate insulating layer 122.

A passivation layer 124 is formed over the entire sub-pixel SP and connection portion CNT to cover the thin film transistor TFT, data line DL, and common line CL. The passivation layer 124 may be formed of the single layer or the multiple layers made of the organic material such as benzo cyclo butene (BCB) or photo-acryl. However, it is not limited thereto and may be formed of inorganic layer/organic layer and inorganic layer/organic layer/inorganic layer.

A first contact hole CH1 and a second contact hole CH2 are respectively formed in the sub-pixel SP and the connection portion CNT by removing a part of the passivation layer 124. The drain electrode 117 of the thin film transistor TFT is exposed to the outside through the first contact hole CH1. The transparent conductive layer 133 is exposed to the outside through the second contact hole CH2. A part of the light shielding layer 135 and the common line CL are also exposed through the second contact hole CH2.

In some examples, the pixel electrode 134 is formed on the passivation layer 124 in the sub-pixel SP, and the connection electrode 138 is formed on the passivation layer 124 in the connection portion CNT.

The pixel electrodes 134 formed in the strip shape with the predetermined width are arranged to be spaced a certain distance apart. The pixel electrode 134 is electrically connected to the drain electrode 117 of the thin film transistor TFT through the first contact hole CH1 formed in the passivation layer 124, so that the external image signal is applied to the pixel electrode 134 through the thin film transistor TFT. The pixel electrode 134 may be made of a transparent metal oxide such as ITO or IZO, but is not limited thereto.

The connection electrode 138 is disposed inside the second contact hole CH2 to connect electrically the common line CL to the transparent conductive layer 133. Since the transparent conductive layer 133 is formed integrally with the common electrode 132, the common voltage supplied through the common line CL is applied to the common electrode 132 through the connection electrode 138. At this time, the connection electrode 138 is also connected to the light shielding layer 135 so that the connection electrode 138 is electrically connected to the transparent conductive layer 133 through the common line CL and the light shielding layer 135.

The liquid crystal layer 150 is formed between the first substrate 140 on which the black matrix 142 and the color filter layer 144 are disposed and the second substrate 110 on which the thin film transistor TFT is disposed, thereby forming the display apparatus 100.

As described above, in the display apparatus 100 according to the present disclosure, the gate electrode 112 is made of the composite material of the metal having good absorption rate such as Mo or MoOx and the ceramic material having good etching characteristics such as Nb₂O₅, so that the reflection of the external light by the gate electrode 112 may be minimized.

In Addition, in the display apparatus 100 according to the present disclosure, the light shielding layer 135 is disposed below the common line CL, so that the reflection of the external light by the common line CL may be minimized.

At this time, the light shielding layer 135 may be made of only the single layer of the first light shielding layer 135a having the good light absorption and light shielding characteristics to prevent the reflection of the external light. Further, the single layer of the first light shielding layer 135a may be disposed to be contacted with the lower surface of the common line CL to prevent the reflection of the external light. However, in this case, the resistance increases due to the first light shielding layer 135a and thus the signal may be delayed.

However, in the present disclosure, since the light shielding layer 135 includes the first light shielding layer 135a having the good light absorption characteristics or the light shielding characteristics and the second light shielding layer 135b having good conductive characteristics disposed thereon, the increase of the resistance caused by the first light shielding layer 135a is offset by the second light shielding layer 135b and as a result the signal delay due to the increase of the resistance may be prevented.

Hereinafter, the method of manufacturing the display apparatus 100 according to the present disclosure will be described with reference to the attached drawings.

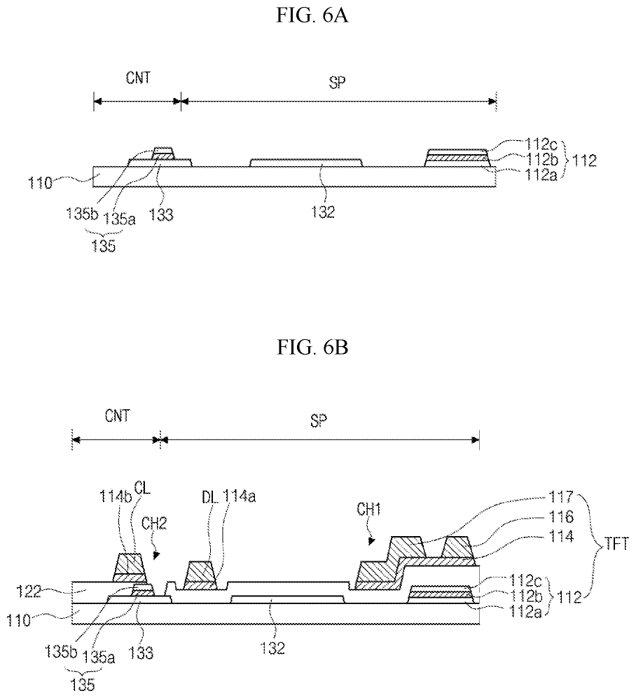

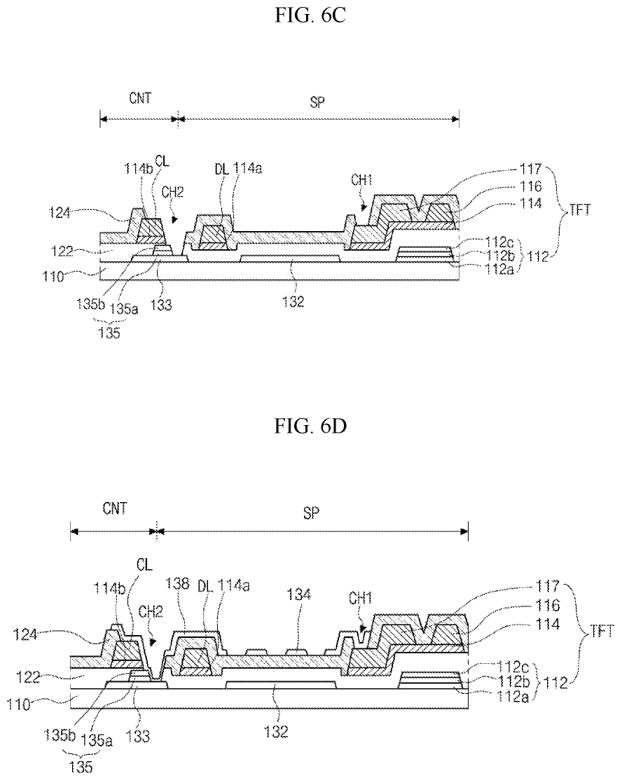

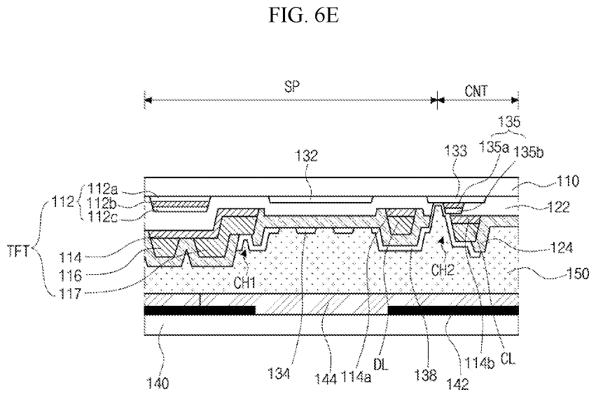

FIGS. 6A to 6E are views illustrating a method of manufacturing a display apparatus according to some aspects of the present disclosure.

As shown in FIG. 6A, first, the transparent metal oxide such as ITO or IZO, the synthetic materials of metal such as Mo or MoOx and the ceramic material such as Nb₂O₅, and the metal such as aluminum (Al), gold (Au), silver (Ag), and copper (Cu) are continuously deposited on the entire area of the second substrate 110. Thereafter, the transparent metal oxide, the synthetic material, and the metal are selectively etched using a halftone mask or a diffraction mask to form the gate electrode 112 including the first gate layer 112a made of the transparent metal oxide, the second gate layer 112b made of the low reflection material having good light absorption characteristics, and the third gate layer 112c made of the metal having good conductivity on the second substrate 110 in the sub-pixel.

At the same time, the common electrode 132 made of the transparent metal oxide such as ITO or IZO is formed on the second substrate 110 in the sub-pixel SP. Further, the transparent conductive layer 133 made of the transparent metal oxide such as ITO or IZO is formed on the second substrate 110 in the connection portion CNT, and the first light shielding layer 135a made of the low reflection material having good light absorption characteristics and the second light shielding layer 135b made of the metal having good conductivity are formed thereon.

Thereafter, as shown in FIG. 6B, the insulating material made of SiNx or SiOx and the semiconductor such as amorphous silicon or polycrystalline silicon are continuously deposited and then selectively etched using the halftone mask or the diffraction mask to form the gate insulating layer 132 over the entire area of the sub- pixels SP and the connection portion CNT. At the same time, the semiconductor layer 114 is formed on the gate electrode 112 in the sub pixel SP, and the first semiconductor pattern 114 and the second semiconductor pattern 1114b are respectively formed in the sub-pixel SP and the connection portion CNT. At this time, the gate insulating layer 122 on the transparent conductive layer 133 is etched to form the second contact hole CH2 through which the transparent conductive layer 133 is exposed to the outside.

Subsequently, the metal such as molybdenum (Mo), aluminum (Al), chromium (Cr), gold (Au), titanium (Ti), nickel (Ni), neodymium (Nd), and copper (Cu) is deposited and etched over the entire area of the sub-pixel SP and the connection portion CNT to form the source and drain electrodes 116 and 117 in sub-pixel, the data line DL on the first semiconductor pattern 114a in the sub-pixel SP, and the common line CL on the second semiconductor pattern 114b in the connection portion CNT. Thereafter, a portion of the semiconductor layer 114 between the source electrode 116 and the drain electrode 117 is etched using the source electrode 116 and the drain electrode 117 as a mask.

Thereafter, as shown in FIG. 6C, the passivation layer 124 is formed by depositing the organic material such as BCB or photo acrylic over the entire area of the sub pixel SP and connection portion CNT. Subsequently, a portion of the passivation layer 124 is etched to form the first contact hole CH1 on the drain electrode 117 and the second contact hole CH2 on the transparent conductive layer 133.

As shown in FIG. 6D, the transparent metal oxide such as ITO or IZO is deposited on the passivation layer 124 and then etched the passivation layer 124 to form the pixel electrode 134 of the strip shape connected to the drain electrode 117 through the first contact hole CH1 and the connection electrode 138 connected electrically to the transparent conductive layer 133, the light shielding layer 135, and the common line CL through the second contact hole CH2.

Thereafter, as shown in FIG. 6E, the black matrix 142 and the color filter layer 144 are formed on the first substrate 140, and then the first substrate 140 and the second substrate 110 are bonded. Subsequently, the liquid crystal layer 150 is formed between the first substrate 140 and the second substrate 110.

As described above, in the display apparatus according to the present disclosure, it is possible to prevent image quality deterioration due to reflection of the external light by forming the light absorption layer or the low reflection material layer having good light absorption rate under the gate electrode.

Further, in the present disclosure, the reflection of the external light in the common line is prevented by disposing the light shielding layer having good light absorption characteristic under the common line, thereby preventing image quality deterioration more efficiently.

The above description and the accompanying drawings are merely illustrative of the technical spirit of the present disclosure, and those of ordinary skill in the art to which the present disclosure pertains may combine configurations within a range that does not depart from the essential characteristics of the present disclosure, various modifications or variations such as separation, substitution and alteration will be possible. Therefore, the embodiments disclosed in the present disclosure are not intended to limit the technical spirit of the present disclosure, but to explain, and the scope of the technical spirit of the present disclosure is not limited by these embodiments.

Claim language or other language reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, or A and B and C. The language “at least one of” a set and/or “one or more” of a set does not limit the set to the items listed in the set. For example, claim language reciting “at least one of A and B” or “at least one of A or B” can mean A, B, or A and B, and can additionally include items not listed in the set of A and B.

What is claimed is:

1. A display apparatus, comprising:
a display panel including a first substrate and a second substrate;
a backlight unit facing the first substrate and configured to supply light to the display panel;
a color filter layer on the first substrate;
a plurality of gate lines and data lines on the second substrate configured to form a plurality of sub-pixels;
a thin film transistor in each of the plurality of sub-pixels on the second substrate;
a pixel electrode and a common electrode in each of the plurality of sub-pixels;
a common line on the second substrate to apply an signal to the common electrode; and
a light shielding layer under the common line,
wherein the light shielding layer includes a first light shielding layer configured to absorb the light and a second light shielding layer made of a metal.

2. The display apparatus of claim 1, wherein the first light shielding layer is formed of material having an extinction coefficient (K) of 0.6<k<1.2.

3. The display apparatus of claim 2, wherein the first light shielding layer is formed of a composite material of the metal and a ceramic material.

4. The display apparatus of claim 3, wherein the metal of the first light shielding layer includes Mo or MoOx, and the ceramic material of the first light shielding layer includes Nb₂O₅.

5. The display apparatus of claim 1, further comprising:
a connection electrode configured to connect the common line, the light shielding layer, and the common electrode.

6. The display apparatus of claim 5, wherein the common electrode is on the second substrate and the light shielding layer is on the common electrode.

7. The display apparatus of claim 6, wherein the thin film transistor includes:
a gate electrode on the second substrate;
a gate insulating layer configured to connect the gate electrode;
a semiconductor layer on the gate insulating layer;
a source electrode and a drain electrode on the semiconductor layer; and
a passivation layer configured to cover the source electrode and the drain electrode.

8. The display apparatus of claim 7, wherein the gate electrode includes:
a first gate layer on the second substrate;
a second gate layer on the first gate layer; and
a third gate layer on the second gate layer.

9. The display apparatus of claim 8, wherein the first gate layer is formed of the same material as the common electrode, the second gate layer is formed of the same material as the first light shielding layer, and the third gate layer is formed of the same material as the second light shielding layer.

10. The display apparatus of claim 7, wherein the pixel electrode is on the passivation layer.

11. The display apparatus of claim 10, wherein a contact hole is formed in the passivation layer and the connection electrode is formed in the contact hole.

12. The display apparatus of claim 11, wherein the connection electrode is formed of the same material as the pixel electrode.

13. The display apparatus of claim 1, wherein adjacent sub-pixels of the plurality of sub-pixels share the data line.

14. A display apparatus, comprising:
a first substrate;
a backlight unit facing the first substrate;
a second substrate configured as a screen on the first substrate to display an image;
a printed circuit board attached to the second substrate and configured to control transmission of light onto the second substrate;
a color filter layer on the first substrate;
a plurality of sub-pixels on the second substrate;
a thin film transistor in each of the plurality of sub-pixels on the second substrate; and
a gate electrode in the thin film transistor having a plurality of gate layers, wherein each of the plurality of gate layers is formed on a different material.

15. The display apparatus of claim 14, wherein the plurality of gate layers include a first gate layer, a second gate layer, and a third gate layer.

16. The display apparatus of claim 15, wherein the second gate layer is formed of a synthesized metal.

17. The display apparatus of claim 15, further comprising:
a transparent conductive layer on the second substrate; and
a light shielding layer on the transparent conductive layer.

18. The display apparatus of claim 17, wherein the light shielding layer includes a first light shielding layer and a second light shielding layer.

19. The display apparatus of claim 18, wherein the second light shielding layer is formed of the same material as the second gate layer.

20. The display apparatus of claim 14, further comprising:
a passivation layer configured to cover the thin film transistor.
